(19) United States
(12) Patent Application Publication
(10) Pub. No.: US 2006/0222029 A1
(43) Pub. Date: Oct. 5, 2006

(54) Semiconductor laser and optical communication system using the same

(75) Inventor: Tsuyoshi Ohgoh, Kanagawa-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/393,713

(22) Filed: Mar. 31, 2006

(30) Foreign Application Priority Data
Mar. 31, 2005 (JP) (PAT.)103810/2005

(51) Int. Cl. H01S 5/00; H01S 3/04

(52) U.S. Cl. 372/45.01; 372/43.01

(57) ABSTRACT

A red semiconductor laser including a first type GaAs substrate having a set of layers sequentially formed on the substrate, which includes at least: a first conductivity type AlInGaP clad layer; an AlInGaP lower optical guide layer; a quantum well active layer made of GaInP or AlInGaP; an AlInGaP upper optical guide layer; a second conductivity type AlInGaP first upper clad layer including a non-doped region formed on the side of the upper clad layer facing the upper optical guide layer; a second conductivity type GaInP heterobuffer layer; and a second conductivity type GaAs cap layer. The second conductivity type carrier concentration at the interface between the first upper clad layer and upper optical guide layer is kept at a value which is less than or equal to 4×10¹⁶ cm⁻³.

### BACKGROUND OF THE INVENTION

1. Field of the Invention

The present invention relates to a semiconductor laser, more specifically a semiconductor laser that includes an AlInGaP mixed crystal, and an optical communication system using the same.

2. Description of the Related Art

AlInGaP red semiconductor lasers with oscillation wavelengths in the range of 630 to 680 nm are widely used as the light source of drive units for optical discs including DVDs (digital versatile discs) and the like, laser pointers, barcode readers, displays and the like, and research and development for the semiconductor lasers are actively going on. Of the optical discs described above, DVD-R/RW systems are constantly expected a faster data recording speed since they deal with large volumes of information, and development efforts for this are actively underway. As the writing speed increases, the time required for pit formation becomes shorter. Consequently, the semiconductor lasers used as the light source is demanded greater optical power output and reliability.

In the mean time, POFs (plastic optical fibers) are drawing attention for use in home network applications in this broadband age, and various signal transmission applications in industry. The red semiconductor laser is also drawing attention for use as the signal light source of optical communication systems using such plastic optical fibers. The red semiconductor lasers, however, need to have an operating life of several hundreds of thousand of hours for such applications, which has been an obstacle for practical use.

Here, the structure of a typical loss guide type red semiconductor laser and the manufacturing method will be described briefly. In the first crystal growth, an n-type AlInGaP lower clad layer; a non-doped lower optical guide layer; a multiquantum well active layer; a non-doped upper optical guide layer; a p-type AlInGaP first upper clad layer; a p-type GaInP etching stop layer; a p-type AlInGaP second upper clad layer; a p-type GaInP heterobuffer layer; and a p-type GaAs cap layer are sequentially formed on an n-type GaAs substrate whose plane orientation is inclined by 5 to 15 degrees from (100) toward (011) plane. The p-type GaAs cap layer, p-type GaInP heterobuffer layer, and p-type AlInGaP second upper clad layer are formed in a ridge shape, and an n-type GaAs current block layer is arranged on the p-type GaInP etching stop layer to bury the ridge in the second crystal growth. Further, in the third crystal growth, a p-type GaAs contact layer is formed on the p-type GaAs cap layer and n-type GaAs current block layer. Thereafter, an n-side electrode is formed on the rear side of the substrate, and a p-side electrode is formed on the contact layer. Here, Si is primarily used as the n-type dopant, and Zn or Mg is used as the p-type dopant.

Such conventional device structure as described above has a problem. That is, the diffusion coefficient of Zn or Mg acting as a p-type dopant is greater in the AlInGaP material than in the AlGaAs material used for infrared semiconductor lasers. Consequently, Zn or Mg is inevitably diffused in the crystal during the crystal growth or heat treatment, and a nonradiative recombination center is formed by the Zn or Mg diffused in the active layer, causing degradation in the device characteristic.

A method for eliminating the problem is proposed as described, for example, in U.S. Pat. No. 5,345,463, in which the diffusion of Zn into the active layer is prevented by making a part of the clad layer adjacent to the active layer as a non-doped layer or providing a layer with a smaller carrier concentration.

Another preventive method is proposed as described, for example, in U.S. Pat. No. 6,798,808, in which a non-doped spacer layer with a thickness of 5 to 10 nm is provided between the p-type upper clad layer and non-doped upper optical guide layer. According to the structure disclosed in the U.S. Pat. No. 6,798,808, the carrier concentration at the interface between the spacer layer and upper optical guide layer is kept within the range of 5×10¹⁷ to 5×10¹⁸ cm⁻³, and the p-type dopant is not diffused into the optical guide layer in which a comparatively large proportion of the light within the waveguide is distributed. Thus, it is described that characteristic degradation of the device due to the optical carrier recombination center arising from the defect formed by the diffusion may be prevented.

The carrier concentration in the clad layer adjacent to the active layer has the effect of increasing the Fermi level, and in effect enhancing the carrier confinement effect into the active layer. Consequently, decreasing the carrier concentration or making a part of the clad layer as a non-doped layer as proposed in the U.S. Pat. No. 5,345,463 results in the degradation in the static characteristic and operating life property. That is, the non-doped layer should have an optimum width, but it is not described in U.S. Pat. No. 5,345,463.

The inventor of the present invention has also reviewed the structure described in U.S. Pat. No. 6,798,808, and verified that the characteristic degradation of the device may not be avoided only by preventing the impurity diffusion at the carrier concentration level of 5×10¹⁷ to 5×10¹⁸ cm⁻³, when high power and high temperature are taken into account. More specifically, the device structured as described above does not show any significant degradation in operating life property when operated at 25 degrees Celsius with output power of around 5 mW. When operated under a higher temperature with higher output power, however, it has been verified that the operating life property is degraded which is seemingly caused by the diffusion of p-type dopant. Further, it has been verified that the device does not satisfy the specification of 200,000 to 300,000 hours of operation required of the signal light source of optical communication systems, although it does not pose any problem for use, for example, as the light source for DVD reading which requires an operating life of 10,000 to 20,000 hours.

Further, the U.S. Pat. No. 6,798,808 defines the thickness of the spacer layer from 5 to 10 nm at the time of crystal growth. The thickness of the spacer layer required for preventing the diffusion of p-type dopant should depend on the temperature and duration of the crystal growth, and unless the concentration profile of p-type dopant is ensured when made into a laser device, it is difficult to obtain an intended performance stably.

In view of the circumstances described above, it is an object of the present invention to provide a semiconductor laser which is superior in static characteristics including operating current and the like with a long operating life by preventing the degradation of active layer arising from the diffusion of p-type dopant such as Zn, Mg, or the like.

It is a further object of the present invention to provide a highly reliable optical communication system ensured by the signal light source with an operating life of 200,000 to 300,000 hours.

### SUMMARY OF THE INVENTION

The semiconductor laser according to the present invention is a red semiconductor laser comprising a first type GaAs substrate having a set of layers sequentially formed thereon, which includes at least:

a first conductivity type AlInGaP clad layer;

an AlInGaP lower optical guide layer;

a quantum well active layer made of GaInP or AlInGaP;

an AlInGaP upper optical guide layer;

a second conductivity type AlInGaP upper clad layer including a non-doped region formed on the side thereof facing the upper optical guide layer;

a second conductivity type GaInP heterobuffer layer; and

a second conductivity type GaAs cap layer,

wherein the second conductivity type carrier concentration at the interface between the upper clad layer and upper optical guide layer is less than or equal to 4×10¹⁶ cm⁻³.

Here, either of the first conductivity type or second conductivity type represents n-type and the other represents p-type. In the structure described above, the second conductivity type carrier concentration in the optical guide layer, in which a comparatively large proportion of the light within the waveguide is distributed, and the multiquantum well active layer is also less than or equal to 4×10¹⁶ cm⁻³.

The second conductivity type carrier concentration at the interface between the upper clad layer and upper optical guide layer may be kept at such small value as described above by, for example, providing a non-doped layer, which has the same composition as the other second conductivity type clad region, on the side of the upper clad layer facing the upper optical guide layer when producing the device, and diffusing the second conductivity type carrier from the second conductivity type region to the non-doped layer after crystal growth.

Preferably, the distance from the region in the second conductivity type upper clad layer where the second conductivity type carrier concentration is 4×10¹⁶ cm⁻³ to the interface between the upper clad layer and upper optical guide layer is less than or equal to 70 nm in order to prevent characteristic degradation due to decrease in the carrier concentration in the upper clad layer.

Further, it is preferable that the second conductivity type carrier is Zn or Mg.

As described above, the carrier concentration in the p-type clad layer brings forth the effect of increasing the Fermi level, and in effect enhancing carrier confinement effect into the active layer. Thus, it is undesirable to extremely reduce the p-type carrier concentration for device characteristic. On the other hand, if the p-type carrier concentration is excessively increased, the p-type carrier largely diffuses during the crystal growth, and it is extremely difficult to form an appropriate second conductivity type (p-type, in this case) carrier concentration profile. Consequently, when the second conductivity type carrier is Zn, which is a p-type carrier, it is preferable that the region in the second conductivity type AlInGaP upper clad layer where Zn concentration is 9×10¹⁷ to 2×10¹⁸ cm⁻³ occupies greater than or equal to half of the layer thickness. Further, in this case, it is preferable that Zn concentration in the second conductivity type GaAs cap layer is 7×10¹⁸ to 2×10¹⁹ cm⁻³.

Further, in the semiconductor laser according to the present invention, it is particularly preferable that a second conductivity type AlInGaP second upper clad layer is provided on the second conductivity type AlInGaP upper clad layer, which is designated to be a first upper clad layer (a certain layer may be provided therebetween); the second conductivity type AlInGaP second upper clad layer, second conductivity type GaInP heterobuffer layer, and second conductivity type GaAs cap layer are formed in a ridge shape; and a first conductivity type GaAs burial layer for current constriction is formed on both sides of the ridge shaped portion.

In the mean time, the optical communication system according to the present invention is an optical communication system, comprising:

a graded index type plastic optical fiber, which includes a polymethacrylate compound, for signal light transmission; and

one of the semiconductor lasers of the present invention for use as the signal light source thereof.

The inventor of the present invention has conducted an intensive study for a method of preventing changes in the position of p-n junction and development of nonradiative recombination center in the active layer arising from the diffusion of second conductivity type carrier, and found that it is necessary to keep the second conductivity type carrier concentration at the interface between the upper optical guide layer and upper clad layer less than or equal to 4×10¹⁶ cm⁻³ to eliminate these problems. If these problems are eliminated, the performance of the semiconductor laser is significantly improved particularly when operated under a high temperature with high output power.

Hereinafter, the advantageous effects of the present invention will be described in detail. The inventor of the present invention has conducted an evaluation test for a broad area semiconductor laser having a basic structure which is identical to that of a second embodiment to be described later in order to examine the relationship between the carrier concentration at the interface between the upper optical guide layer and upper clad layer, and the operating life property of the device. The broad area structure requires a larger amount of drive current compared with the single mode structure. Thus, the use of the semiconductor laser with the broad area structure allows the evaluation test to be performed under more severe conditions. Here, a wider emission width requires a greater amount of drive current. If it exceeds 70 μm, however, the performance of the device is degraded significantly. Therefore, a semiconductor laser with an emission width of 50 μm was used for the evaluation test. The same effect may be obtained by using a single mode semiconductor laser operated at high output power. In such a case, however, end face degradation is concerned. Consequently, in the evaluation test, a broad area structure was used with a constant optical power output of 5 mW to avoid the end face degradation. Here, the first conductivity type is n-type, the second conductivity type is p-type, and Zn is used as the second conductivity type (p-type) dopant.

A Zn concentration profile was measured for a produced wafer using a SIMS (secondary ion mass spectrometry). The analyzer “IMS-4F” available from CAMECA Corporation in France was used for the measurement. Based on the measurement results, semiconductor lasers having different concentration profiles were produced and subjected to a 5,000 hour operating life test under the conditions of 50 degrees Celsius, 5 mW output, and APC driving. In the test, the time interval from the initial time to the time when the drive current is increased to 1.2 times of the initial value is measured as the estimated operating life. The result is shown in FIG. 4. The graph indicates that the operating life property is significantly improved if the Zn concentration at the interface between the p-type upper clad layer and adjacent upper optical guide layer is kept less than or equal to 4×10¹⁶ cm⁻³.

The Zn concentration may be kept less than or equal to 4×10¹⁶ cm⁻³ by making the film thickness ι of the non-doped layer thicker at the time of the crystal growth to prevent the Zn diffusion. The carrier concentration in the p-type upper clad layer, however, has the effect of increasing the Fermi level, and in effect enhancing the carrier confinement effect into the active layer, it is undesirable to make the film thickness ι unnecessarily thick. Therefore, the relationship between the distance from the region in the p-type upper clad layer where the Zn carrier concentration is 4×10¹⁶ cm⁻³ to the interface between the upper clad layer and upper optical guide layer, and the operating life property was examined.

The result is shown in FIG. 5. Here, the position of the interface between the p-type upper clad layer and upper optical guide layer is defined as the reference position (distance=0), and the distance from the reference position to the region where the Zn carrier concentration is 4×10¹⁶ cm⁻³ is indicated with plus sign if the region is located in the p-type upper clad layer and with minus sign if it is located in the upper optical guide layer. Accordingly, the graph indicates that the greater the distance in plus direction the greater the non-doped region in the upper clad layer, and the greater the distance in minus direction the greater the Zn concentration in the upper optical guide layer. FIG. 5 indicates that more than 1,000 hours of operating life of the device may be obtained if the region in the p-type upper clad layer where the Zn carrier concentration is 4×10¹⁶ cm⁻³ locates within a distance of 70 nm from the interface between the upper clad layer and upper optical guide layer. In the present device, the region in the p-type upper clad layer where the Zn concentration is 9×10¹⁷ to 2×10¹⁸ cm⁻³ occupies greater than or equal to half of the layer thickness. On the other hand, the Zn concentration in the GaAs cap layer is 7×10¹⁸ to 2×10¹⁹ cm⁻³.

It will be appreciated that the values of the carrier concentration in the evaluation test described above should not be construed as limiting the scope of the present invention. Various changes and modifications may be made within the technical concept of the present invention. But these values described above are preferable when Zn is used as the p-type dopant from the view point of device performance.

The p-type carrier concentration in the upper clad layer and GaAs cap layer governs the amount of p-type carrier diffusion. Therefore, it is necessary to adjust the thickness of the non-doped layer provided on the side of the upper clad layer facing the upper optical guide layer when producing the device if the amount of carrier concentration in these layers is to be changed considerably.

So far is the examination result of a semiconductor laser with a board area structure. Identical examination has also been performed for a semiconductor laser which was single-moded by processing a wafer having the same Zn concentration profile as that described above with a low temperature that does not induce p-type dopant diffusion. As a result, the estimated operating life is extended more than 10 times, and the result reflecting roughly the same pattern as described above has been obtained. More specifically, a highly reliable and practical semiconductor laser with an estimated operating life of more than 10,000 hours and an oscillation wavelength in the 660 nm band without any appreciable variation in the drive current may be obtained by regulating the p-type carrier concentration in the manner as defined by the present invention.

### BRIEF DESCRIPTION OF THE DRAWINGS

FIG. 1 is a side cross-sectional view of the semiconductor laser according to a first embodiment of the present invention.

FIG. 2 is a side cross-sectional view of the semiconductor laser according to a second embodiment of the present invention.

FIG. 3 is a schematic diagram of the optical communication system according to an embodiment of the present invention, which employs one of the semiconductor lasers of the present invention.

FIG. 4 is a graph illustrating the relationship between Zn concentration at the interface between the first upper clad layer and upper optical guide layer, and estimated operating life.

FIG. 5 is a graph illustrating the relationship between the distance from the interface between the first upper clad layer and upper optical guide layer to the region in the first upper clad layer where the Zn carrier concentration is 4×10¹⁶ cm⁻³, and estimated operating life.

FIG. 6 is a schematic view illustrating a p-type carrier concentration profile of the semiconductor laser according to the present invention.

### DESCRIPTION OF THE PREFERRED EMBODIMENTS

Hereinafter, embodiments of the present invention will be described with reference to the accompanying drawings.

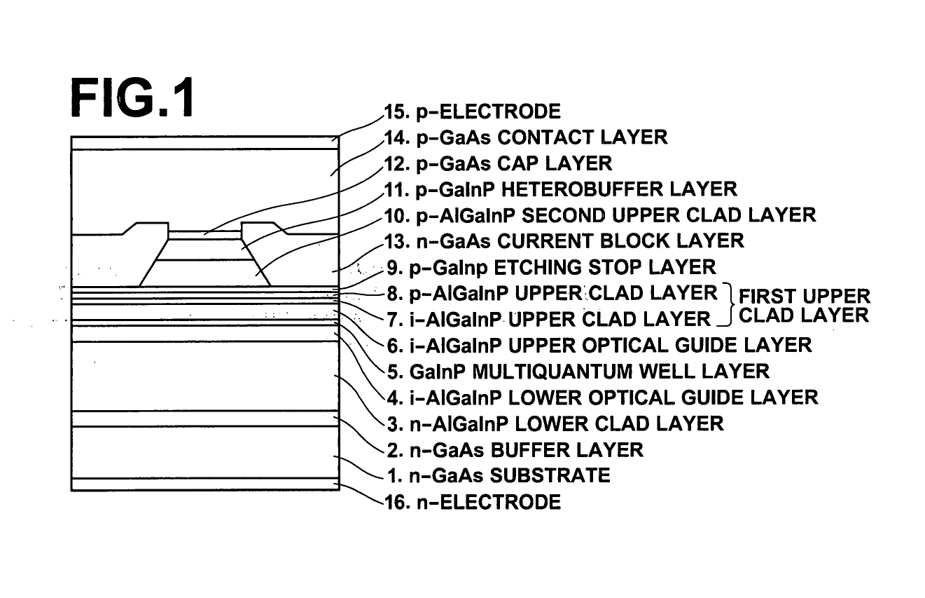

FIG. 1 is a schematic sectional elevational view of an AlInGaP red semiconductor laser. As shown in FIG. 1, the semiconductor laser of the present embodiment comprises an n-type GaAs substrate 1 having a set of layers sequentially formed thereon, which includes: an n-type GaAs buffer layer 2 (thickness: 0.2 μm); an n-type (Al_{0.7}Ga_{0.3})_{0.51}In_{0.49}P lower clad layer 3 (thickness: 1.2 μm); a non-doped (Al_{0.5}Ga_{0.5})_{0.51}In_{0.49}P lower optical guide layer 4 (thickness: 0.08 nm); a GaInP multiquantum well active layer 5; a non-doped (Al_{0.5}Ga_{0.5})_{0.51}In_{0.49}P upper optical guide layer 6 (thickness: 0.08 nm); a non-doped (Al_{0.7}Ga_{0.3})_{0.51}In_{0.49}P upper clad layer 7 (thickness: ι<0.2 μm); a p-type (Al_{0.7}Ga_{0.3})_{0.51}In_{0.49}P upper clad layer 8 (thickness: 0.2 μm−ι); a p-type In_{0.43}Ga_{0.57}P etching stop layer 9 (thickness: 10 to 15 nm); a p-type (Al_{0.7}Ga_{0.3})_{0.51}In_{0.49}P second upper clad layer 10 (thickness: 1.0 μm); a p-type Ga_{0.51}In_{0.49}P heterobuffer layer 11 (thickness: 0.5 μm); a p-type GaAs cap layer 12 (thickness: 0.2 μm); and a p-type GaAs contact layer 14 (thickness: 2.0 μm).

The (Al_{0.7}Ga_{0.3})_{0.51}In_{0.49}P second upper clad layer 10, p-type Ga_{0.51}In_{0.49}P heterobuffer layer 11, and p-type GaAs cap layer 12 are formed in a ridge shape, and an n-type GaAs current block layer 13 (thickness: 1.3 μm) for current constriction is formed on both sides of the ridge shaped section. A p-electrode 15 is formed on the GaAs cap layer, and an n-electrode 16 is formed on the rear side of the n-type GaAs substrate 1.

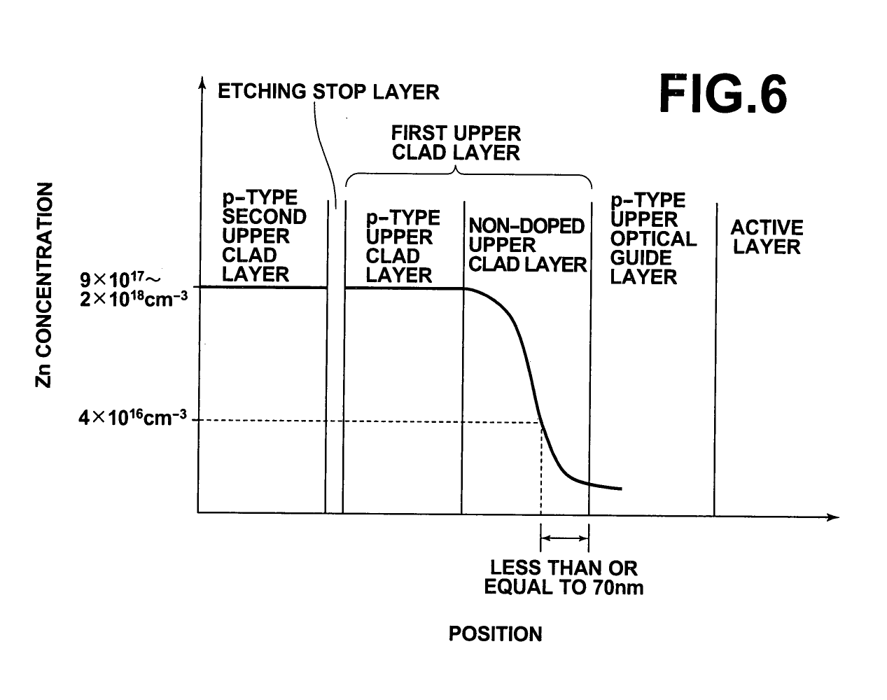

In the present embodiment, the non-doped (Al_{0.7}Ga_{0.3})_{0.51}In_{0.49}P upper clad layer 7 and p-type (Al_{0.7}Ga_{0.3})_{0.51}In_{0.49}P upper clad layer 8 constitute a first upper clad layer. The concentration profile of Zn, which is a p-type carrier, in the first upper clad layer and the layers on both sides thereof is as shown in FIG. 6. As shown in FIG. 6, the first upper clad layer as a whole is a p-type clad layer with partly including a non-doped region (upper clad layer 7).

In producing the semiconductor laser of the present embodiment, the crystal growth is performed, for example, by metalorganic chemical vapor deposition (MOCVD) method. As for the source gases, TEG (triethylgallium), TMA (trimethylaluminum), TMI (trimethylindium), AsH₃ (arsine); PH₃ (phosphine) are used. SiH₄ (silane) is used as the n-type dopant, and DEZ (diethyl zinc) or Cp₂Mg (Bis cyclopentadieny magnesium) is used as the p-type dopant. Hereinafter, a specific method for manufacturing the semiconductor laser of the present embodiment will be described.

In the first crystal growth by MOCVD method under a growth temperature of 685 to 735 degrees Celsius with a growth pressure of 10.3 kPa, then-type GaAs buffer layer 2; n-type (Al_{0.7}Ga_{0.3})_{0.51}In_{0.49}P lower clad layer 3; non-doped (Al_{0.5}Ga_{0.5})_{0.51}In_{0.49}P lower optical guide layer 4; GaInP multiquantum well active layer 5; non-doped (Al_{0.5}Ga_{0.51})_{0.51}In_{0.49}P upper optical guide layer 6; non-doped (Al_{0.7}Ga_{0.3})_{0.51}In_{0.49}P upper clad layer 7: p-type (Al_{0.7}Ga_{0.3})_{0.51}In_{0.49}P upper clad layer 8; p-type In_{0.43}Ga_{0.57}P etching stop layer 9; p-type (Al_{0.7}Ga_{0.3})_{0.51}In_{0.49}P second upper clad layer 10; p-type Ga_{0.51}In_{0.49}P heterobuffer layer 11; and p-type GaAs cap layer 12 are sequentially formed on the n-type GaAs substrate 1 whose plane orientation is inclined by 10 to 15 degrees from (100) toward (011) plane.

Then, a SiO₂ selective growth mask, which is a dielectric mask, is formed thereon, and the p-type GaAs cap layer 12; p-type Ga_{0.51}In_{0.49}P heterobuffer layer 11, and p-type (Al_{0.7}Ga_{0.3})_{0.51}In_{0.49}P second upper clad layer 10 are etched to form a mesastripe ridge structure using the mask.

Thereafter, in the second crystal growth by the selective growth method using the SiO₂ mask, the n-type GaAs current block layer 13 is formed on the p-type GaInP etching stop layer 9 except for the area of the ridge structure. Further, in the third crystal growth, the p-type GaAs contact layer 14 is formed on the entire surface of the mesastripe and current block layer 13 after the SiO₂ mask is removed.

Then, the substrate is grinded until the overall thickness becomes around 100 μm, and finally the n-electrode 16 is formed on the rear side of the substrate, and the p-electrode 15 is formed on the contact layer 14 by vapor deposition and heat treatment. A laser bar with a resonator length of around 0.5 to 1.5 mm is cut out from this sample by cleavage, and optical films of low and high reflectance are coated on the resonator surfaces. Thereafter, it is made into an individual chip by cleavage to form a semiconductor laser.

Here, the thickness ι of the non-doped (Al_{0.7}Ga_{0.3})_{0.51}In_{0.49}P upper clad layer 7 is selected such that p-type carrier concentration at the interface between the upper optical guide layer 6 and first upper clad layer (more specifically, non-doped (Al_{0.7}Ga_{0.3})_{0.51}In_{0.49}P upper clad layer 7) is less than or equal to 4×10¹⁶ cm⁻³ after the crystal growth. The thickness ι is dependent on the growth temperature, plane orientation of the substrate, molar ratio between a III group organic metal and a V group source gas, and p-type carrier concentration in the p-type first and second upper clad layers so that it is necessary to select an appropriate thickness by taking into account the crystal growth conditions.

The inventor of the present invention created the semiconductor laser of the present embodiment using a 10 degree inclined substrate under crystal growth conditions of a growth temperature of 700 degrees Celsius, a p-type carrier concentration of 1×10¹⁸ cm⁻³ in the p-type clad layers, and a molar ratio of 150 to 600 between a III group organic metal and a V group source gas, and performed a SIMS analysis. As a result, it has been found that the p-type carrier concentration at the interface described above may be kept less than or equal to 4×10¹⁶ cm⁻³ and the advantageous effects as described above may be obtained by setting the design value of the thickness ι at 75 to 125 nm.

When Mg is used as the p-type dopant, the diffusion length becomes smaller compared with Zn, and a smaller thickness ι is required. To be more precise, it is likely that the diffusion of p-type dopant may occur during the heat treatment process in the regrowth and electrode forming processes after the first crystal growth. Thus, in order to keep the carrier concentration at the interface between the upper optical guide layer and first upper clad layer less than or equal to 4×10¹⁶ cm⁻³ in the final device state, it is necessary to determine the thickness ι by taking into account the diffusion length during the heat treatment process in the regrowth and electrode forming processes. It is possible, however, to prevent the diffusion of p-type dopant after the first crystal growth by appropriately selecting the temperature and duration of the heat treatment process. If that is the case, the growth conditions described above may be applied.

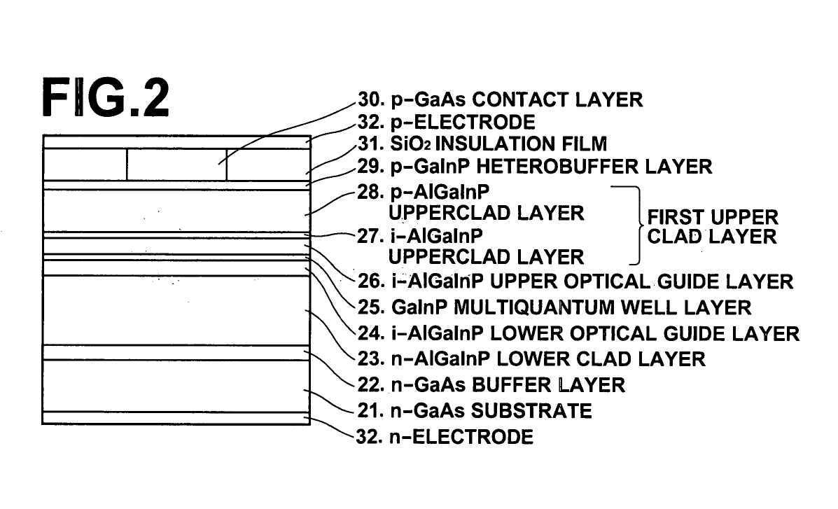

Hereinafter, the semiconductor laser according to a second embodiment of the present invention will be described. FIG. 2 is a schematic sectional elevational view of an AlInGaP red semiconductor laser of the present embodiment. Whereas the semiconductor laser according to the first embodiment has a single mode structure, the semiconductor laser of the present embodiment has a broad area structure.

As shown in FIG. 2, the semiconductor laser of the present embodiment comprises an n-type GaAs substrate 21 having a set of layers sequentially formed thereon, which includes: an n-type GaAs buffer layer 22 (thickness: 0.2 μm); an n-type (Al_{0.7}Ga_{0.3})_{0.51}In_{0.49}P lower clad layer 23 (thickness: 1.2 μm); a non-doped (Al_{0.5}Ga_{0.5})_{0.51}In_{0.49}P lower optical guide layer 24 (thickness: 0.08 nm); a GaInP multiquantum well active layer 25; a non-doped (Al_{0.5}Ga_{0.5})_{0.51}In_{0.49}P upper optical guide layer 26 (thickness: 0.08 nm); a non-doped (Al_{0.7}Ga_{0.3})_{0.51}In_{0.49}P upper clad layer 27 (thickness: ι<0.2 μm); a p-type (Al_{0.7}Ga_{0.3})_{0.51}In_{0.49}P upper clad layer 28 (thickness: 0.2 μm−ι); a p-type Ga_{0.51}In_{0.49}P heterobuffer layer 29 (thickness: 0.5 μm); and a p-type GaAs contact layer 30 (thickness: 0.2 μm).

A part of the p-type GaAs contact layer 30 is kept in a stripe shape, and a SiO₂ insulation film 31 is formed on both sides thereof. A p-electrode 32 is formed on the p-type GaAs contact layer 30, and an n-electrode 33 is formed on the rear side of the n-type GaAs substrate 21.

In the present embodiment, the non-doped (Al_{0.7}Ga_{0.3})_{0.51}In_{0.49}P upper clad layer 27 and p-type (Al_{0.7}Ga_{0.3})_{0.51}In_{0.49}P upper clad layer 28 constitute a first upper clad layer. The concentration profile of Zn, which is a p-type carrier, in the first upper clad layer is identical to that shown in FIG. 6.

In producing the semiconductor laser of the present embodiment, the crystal growth is performed, for example, by MOCVD method. That is, in the first crystal growth by MOCVD method under a growth temperature of 700 degrees Celsius with a growth pressure of 10.3 kPa, the n-type GaAs buffer layer 22; n-type (Al_{0.7}Ga_{0.3})_{0.51}In_{0.49}P lower clad layer 23; non-doped (Al_{0.5}Ga_{0.5})_{0.51}In_{0.49}P lower optical guide layer 24; GaInP multiquantum well active layer 25; non-doped (Al_{0.5}Ga_{0.5})_{0.51}In_{0.49}P upper optical guide layer 26; non-doped (Al_{0.7}Ga_{0.3})_{0.51}In_{0.49}P upper clad layer 27: p-type (Al_{0.7}Ga_{0.3})_{0.51}In_{0.49}P upper clad layer 28; p-type Ga_{0.51}In_{0.49}P heterobuffer layer 29; and p-type GaAs contact layer 30 are sequentially formed on the n-type GaAs substrate 21. As in the first embodiment, the thickness ι of the non-doped (Al_{0.7}Ga_{0.3})_{0.51}In_{0.49}P upper clad layer 27 is selected such that p-type carrier concentration at the interface between the upper optical guide layer 26 and first upper clad layer (more specifically, non-doped (Al_{0.7}Ga_{0.3})_{0.51}In_{0.49}P upper clad layer 27) is less than or equal to 4×10¹⁶ cm⁻³ after the crystal growth.

Then, the p-type GaAs contact layer 30 outside of the stripe region having a width around 50 μm is etched and removed by photolithography with sulfuric acid etchant. The etching is automatically stopped at the p-type Ga_{0.51}, In_{0.49}P heterobuffer layer 29. Then, the SiO₂ insulation film 31 is formed on the surface, and the SiO₂ film 31 on the stripe region is removed in a stripe shape. Thereafter, the substrate is grinded until the overall thickness becomes around 100 μm, and finally the p-electrode 32 is formed on the p-type GaAs contact layer 30 and the n-electrode 33 is formed on the rear side of the n-type GaAs substrate 21 by vapor deposition and heat treatment.

A laser bar with a resonator length of around 0.5 to 1.5 mm is cut out from this sample by cleavage, and optical films of low and high reflectance are coated on the resonator surfaces. Thereafter, it is made into an individual chip by cleavage to form a semiconductor laser.

In the present embodiment, the carrier concentration at the interface between the upper optical guide layer 26 and first upper clad layer is also kept less than or equal to 4×10¹⁶ cm⁻³, so that the advantageous effects identical to those of the first embodiment may be obtained.

In the first and second embodiments, the quantum well active layer may be a strain active layer having a compressive or tensile strain, as well as a non-strain layer. In the multiquantum well layer, GaInP or AlInGaP may be used as the active layer, and AlInGaP having the identical composition to that of the optical guide layer may be used as the barrier layer. The composition ratio of In_{0.49}Ga_{0.51} and In_{0.49}(Al_{z4}Ga_{1-z4})_{0.51}P described in the embodiments indicates lattice matching to the GaAs substrate, and the value is not limited to this if lattice matching to GaAs is achieved.

It will be appreciated that the present invention should not be construed as limited to the specific embodiments set forth herein. Various modifications and changes based on the spirit of the present invention may be made. The present invention may be applied to real refractive index waveguide type semiconductor lasers, semiconductor lasers with a diffraction grating, and the like, as well as loss guide type semiconductor lasers described in the embodiments and gain waveguide type semiconductor lasers.

Further, in the embodiments, the semiconductor lasers have a single emitter structure constituted by a single emitting region. But the present invention may also be applied to a bar laser in which the emitters are monolithically arranged in a one-dimensional array, and an array laser in which the bar lasers are arranged two-dimensionally. Still further, in the embodiments described above, the GaAs substrate is an n-type conductive substrate. But it may be a p-type conductive substrate, in which case all that is required is to reverse the conductivity type of all of the layers described above.

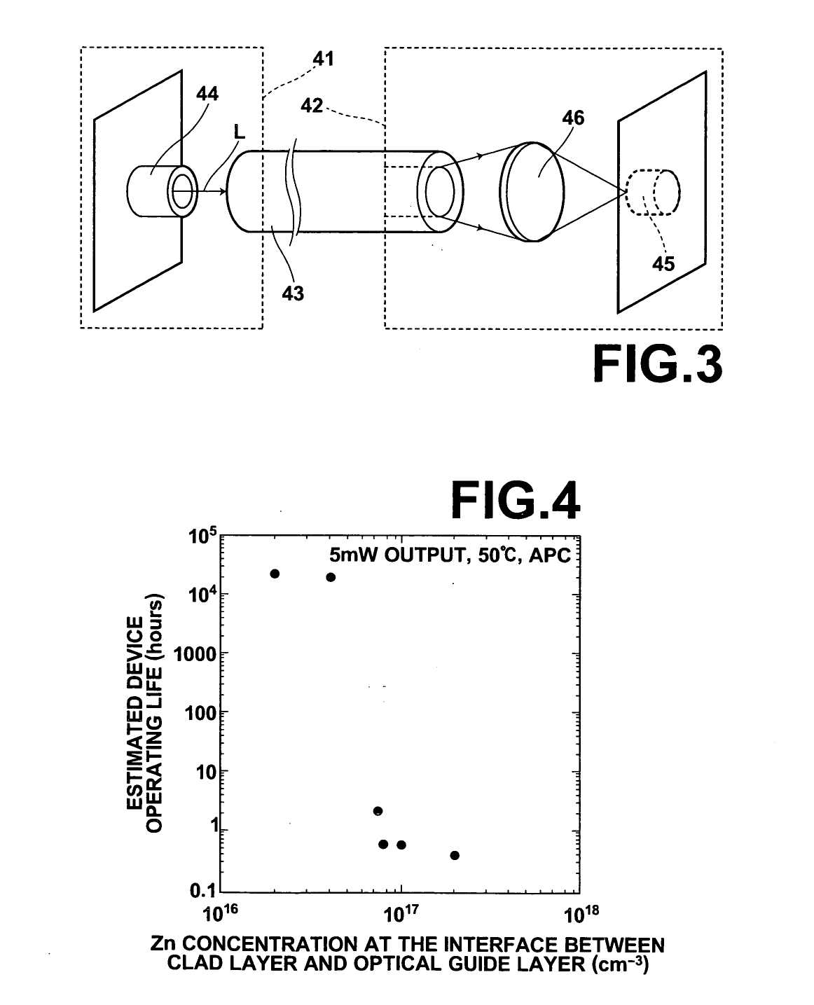

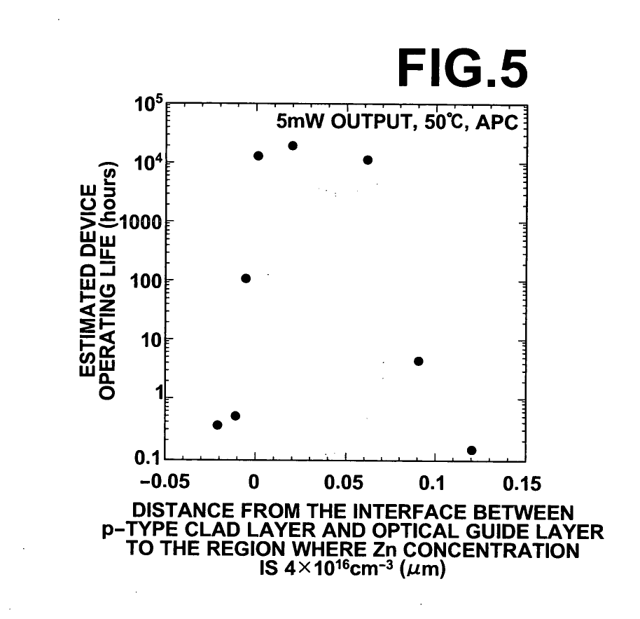

Hereinafter, an embodiment of the optical communication system of the present invention will be described with reference to FIG. 3. The optical communication system of the present embodiment uses a graded index type plastic optical fiber (GI-POF) for signal light transmission. The GI-POF is a multimode optical fiber having a smooth refractive index distribution with highest in the center and lowest in the periphery, and may realize Gbps (gigabits/second) large capacity optical communication. Further, it is more resistant to bending and vibration compared with an inorganic optical fiber using quartz as the core material and characterized by a large diameter of not less than 200 μm.

The optical communication system according to the present embodiment includes a transmitting section 41, a receiving section 42, and a GI-POF 43 for connecting them. A light emitting element 44 provided as the signal light source of the transmitting section 41 emits an optical signal L, which is transmitted through the GI-POF 43 and a converging lens 46, and received by a light receiving element 45 such as a MSM type photodiode or the like.

The GI-POF 43 used in the present embodiment includes a core made of polymerized composition including a polymethacrylate compound, and has a low loss transmission band around the wavelength range of 640 to 660 nm. Consequently, a light emitting element with an oscillation wavelength in the range of 640 to 660 nm is appropriate for use as the light emitting element 44. Thus, the red semiconductor laser according to the first or second embodiment may preferably be used. Here, an operating life of 200,000 to 300,000 hours is required of the red semiconductor laser as the communication light source, although the optical power thereof may be as low as around 5 mW. The semiconductor lasers according to the present invention may satisfy such requirement since they have achieved a prolonged operating life as described above.

So far the embodiment of the optical communication system in which either of the semiconductor lasers of the present invention is used as the signal light source of the system has been described. But the semiconductor lasers of the present invention are not limited to such application, and it may, of course, be used as the light source in various fields, such as high speed information/image processing, communication, measurement, medicine, printing, and the like.

What is claimed is:

1. A red semiconductor laser, comprising a first type GaAs substrate having a set of layers sequentially formed thereon, which includes at least:
a first conductivity type AlInGaP clad layer;
an AlInGaP lower optical guide layer;
a quantum well active layer made of GaInP or AlInGaP;
an AlInGaP upper optical guide layer;
a second conductivity type AlInGaP upper clad layer including a non-doped region formed on the side thereof facing the upper optical guide layer;
a second conductivity type GaInP heterobuffer layer; and
a second conductivity type GaAs cap layer,
wherein the second conductivity type carrier concentration at the interface between the upper clad layer and upper optical guide layer is less than or equal to 4×10¹⁶ cm⁻³.

2. The semiconductor laser according to claim 1, wherein the distance from the region in the second conductivity type upper clad layer where the second conductivity type carrier concentration is 4×10¹⁶ cm⁻³ to the interface between the upper clad layer and upper optical guide layer is less than or equal to 70 nm.

3. The semiconductor laser according to claim 1, wherein the second conductivity type carrier is Zn.

4. The semiconductor laser according to claim 2, wherein the second conductivity type carrier is Zn.

5. The semiconductor laser according to claim 3, wherein the region in the second conductivity type AlInGaP upper clad layer where Zn concentration is 9×10¹⁷ to 2×10¹⁸ cm⁻³ occupies greater than or equal to half of the layer thickness.

6. The semiconductor laser according to claim 4, wherein the region in the second conductivity type AlInGaP upper clad layer where Zn concentration is 9×10¹⁷ to 2×10¹⁸ cm⁻³ occupies greater than or equal to half of the layer thickness.

7. The semiconductor laser according to claim 5, wherein Zn concentration in the second conductivity type GaAs cap layer is 7×10¹⁸ to 2×10¹⁹ cm⁻³.

8. The semiconductor laser according to claim 6, wherein Zn concentration in the second conductivity type GaAs cap layer is 7×10 ¹⁸ to 2×10¹⁹ cm⁻³.

9. The semiconductor laser according to claim 1, wherein the second conductivity type carrier is Mg.

10. The semiconductor laser according to claim 2, wherein the second conductivity type carrier is Mg.

11. The semiconductor laser according to claim 1, wherein:
a second conductivity type AlInGaP second upper clad layer is provided on the second conductivity type AlInGaP upper clad layer, which is designated to be a first upper clad layer;
the second conductivity type AlInGaP second upper clad layer, second conductivity type GaInP heterobuffer layer, and second conductivity type GaAs cap layer are formed in a ridge shape; and
a first conductivity type GaAs burial layer for current constriction is formed on both sides of the ridge shaped portion.

12. The semiconductor laser according to claim 2, wherein:
a second conductivity type AlInGaP second upper clad layer is provided on the second conductivity type AlInGaP upper clad layer, which is designated to be a first upper clad layer;
the second conductivity type AlInGaP second upper clad layer, second conductivity type GaInP heterobuffer layer, and second conductivity type GaAs cap layer are formed in a ridge shape; and
a first conductivity type GaAs burial layer for current constriction is formed on both sides of the ridge shaped portion.

13. The semiconductor laser according to claim 3, wherein:
a second conductivity type AlInGaP second upper clad layer is provided on the second conductivity type AlInGaP upper clad layer, which is designated to be a first upper clad layer;
the second conductivity type AlInGaP second upper clad layer, second conductivity type GaInP heterobuffer layer, and second conductivity type GaAs cap layer are formed in a ridge shape; and
a first conductivity type GaAs burial layer for current constriction is formed on both sides of the ridge shaped portion.

14. The semiconductor laser according to claim 4, wherein:
a second conductivity type AlInGaP second upper clad layer is provided on the second conductivity type AlInGaP upper clad layer, which is designated to be a first upper clad layer;
the second conductivity type AlInGaP second upper clad layer, second conductivity type GaInP heterobuffer layer, and second conductivity type GaAs cap layer are formed in a ridge shape; and
a first conductivity type GaAs burial layer for current constriction is formed on both sides of the ridge shaped portion.

15. The semiconductor laser according to claim 1, wherein the laser is structured to oscillate in multimode with an emission width less than or equal to 70 μm.

16. The semiconductor laser according to claim 2, wherein the laser is structured to oscillate in multimode with an emission width less than or equal to 70 μm.

17. An optical communication system, comprising:
a graded index type plastic optical fiber, which includes a polymethacrylate compound, for signal light transmission; and
the semiconductor laser according to claim 1 for use as the signal light source thereof.

18. An optical communication system, comprising:
a graded index type plastic optical fiber, which includes a polymethacrylate compound, for signal light transmission; and
the semiconductor laser according to claim 2 for use as the signal light source thereof.

19. An optical communication system, comprising:
a graded index type plastic optical fiber, which includes a polymethacrylate compound, for signal light transmission; and
the semiconductor laser according to claim 3 for use as the signal light source thereof.

20. An optical communication system, comprising:
a graded index type plastic optical fiber, which includes a polymethacrylate compound, for signal light transmission; and
the semiconductor laser according to claim 4 for use as the signal light source thereof.
